(19) United States
(12) Patent Application Publication
(10) Pub. No.: US 2018/0331284 A1
(43) Pub. Date: Nov. 15, 2018

(54) THRESHOLD VOLTAGE CONTROL OF MEMORY CELL SELECTOR FOR PHASE CHANGE AND RESISTIVE RANDOM ACCESS MEMORY ARRAYS

(71) Applicants: International Business Machines Corporation, Armonk, NY (US); MACRONIX INTERNATIONAL CO., LTD, Hsin-chu (TW)

(72) Inventors: Matthew J. BrightSky, Pound Ridge, NY (US); Fabio Carta, White Plains, NY (US); Huai-Yu Cheng, Yorktown Heights, NY (US); Wanki Kim, Chappaqua, NY (US)

(21) Appl. No.: 15/590,014

(22) Filed: May 9, 2017

(51) Int. Cl. H01L 45/00; H01L 27/24

(52) U.S. Cl. CPC H01L 45/141; H01L 27/2409; H01L 45/1608; H01L 27/2463; H01L 45/1683; H01L 45/06; H01L 45/1666

(57) ABSTRACT

A memory access device that includes a first terminal with a first terminal workfunction and a chalcogenide-based selector layer with a first surface and a second surface opposite the first surface. A first control metal layer is positioned in physical and electrical contact with the first terminal and the first surface of the chalcogenide-based selector layer. The first control metal layer includes a first control workfunction different than the first terminal workfunction. A second terminal with a second terminal workfunction is positioned proximate the second surface of the chalcogenide-based selector layer.

### BACKGROUND

The present invention is directed toward computer memory, and more particularly to memory access devices for resistive memory arrays.

Scaling dimensions of phase change random access memory (PCRAM) and resistive random access memory (RRAM) to achieve dense cross-point memory requires development of a selector device with a small footprint. Typically, transistors have a larger footprint and limit the memory density achievable. Two-terminal access devices are more suitable selectors for scaled memory technology.

A one-selector one-resistor (1S1R) structure is often ideal for use in cross-point memory which allow high density and monolithic 3D integration. Chalcogenide based selectors are nonlinear devices that exhibit current conduction above a threshold voltage Vth and high resistance below a holding voltage Vh.

Low-power applications of large cross-point memory typically require low threshold voltage for the selecting device, as well as low resistance metal lines for driving bit lines and word lines. Threshold voltage of selector devices can be tuned by tuning the thickness of the switching layer. However, a decrease in thickness of the switching layer can cause an increase of device “off” current which, in turn, can increase power consumption of the memory array.

Low resistance metal word and bit lines are often necessary for a scaled dimension memory array to decrease the loading effect and driving voltage of the array. However, low-resistance metal may not have suitable properties to be in direct contact with the switching layer.

### BRIEF SUMMARY

Accordingly, aspects of the present invention include a memory access device with threshold voltage control for cross-point PCRAM or RRAM memory arrays.

One example aspect of the present invention is a novel memory access device. The memory access device includes a first terminal with a first terminal workfunction and a chalcogenide-based selector layer with a first surface and a second surface. A first control metal layer is positioned in physical and electrical contact with the first terminal and the first surface of the chalcogenide-based selector layer. The first control metal layer includes a first control workfunction different than the first terminal workfunction. A second terminal with a second terminal workfunction is positioned proximate the second surface, opposite the first surface, of the chalcogenide-based selector layer.

Another example aspect of the present invention is a method for fabricating a memory access device. The method includes depositing a first terminal layer over a substrate. The first terminal layer includes a first terminal workfunction. Another depositing operation deposits a first control metal layer over and in physical contact with the first terminal layer. The first control metal layer includes a first control workfunction different than the first terminal workfunction. Another depositing operation deposits a chalcogenide-based selector layer over the first terminal layer. Another depositing deposits a second control metal layer over and in physical contact with the chalcogenide-based selector layer. The second control metal layer includes a second control workfunction. Another depositing operation deposits a second terminal layer over and in physical with the second control metal layer. The second control metal layer includes a second terminal workfunction different than the second terminal workfunction. A patterning operation patterns the first control metal layer, the chalcogenide-based selector layer, and the second control metal layer into an access device pillar.

Yet a further example aspect of the present invention is a memory device an array of memory cells. Each memory cell in the array of memory cells includes an access device and a resistive memory electrically coupled to the access device. The resistive memory material is programmable to at least two resistive states. Each access device includes a first terminal with a first terminal workfunction, a chalcogenide-based selector layer with a first surface and a second surface opposite the first surface, a first control metal layer in physical and electrical contact with the first terminal and the first surface of the chalcogenide-based selector layer. The first control metal layer has a first control workfunction different than the first terminal workfunction. The access device further includes a second terminal with a second terminal workfunction. The second terminal is positioned proximate the second surface of the chalcogenide-based selector layer.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 shows an example memory access device contemplated by the present invention.

FIG. 2 is graph comparing threshold voltages of three different memory access devices contemplated by the present invention.

FIG. 3 shows an alternate example embodiment of the memory access device.

FIG. 4 shows another alternate example embodiment of the memory access device.

FIG. 5 shows an example embodiment of a memory device contemplated by the present invention.

FIG. 6 shows an example method for fabricating a memory access device, as contemplated by the present invention.

FIG. 7A shows a hard mask layer applied over layers forming the memory access device.

FIG. 7B is a view of FIG. 7A along section line 7B.

FIG. 8A shows access device fabrication after a stack etch is applied, with the first terminal layer 706 used to form a word line.

FIG. 8B is a view of FIG. 8A along section line 8B.

FIG. 9A shows a dielectric layer deposited over and surrounding an access device stack.

FIG. 9B is a view of FIG. 9A along section line 9B.

FIG. 10A shows a second hard mask deposited and patterned over the access device layers.

FIG. 10B is a view of FIG. 10A along section line 10B.

FIG. 11A shows the access device etched, with an etch stop at a first terminal layer.

FIG. 11B is a view of FIG. 11A along section line 11B.

FIG. 12A shows a resulting structure after a dielectric surrounding operation.

FIG. 12B is a view of FIG. 12A along section line 12B.

FIG. 13A shows forming a pore within the dielectric layer, above and in physical contact with a second control metal layer.

FIG. 13B is a view of FIG. 13A along section line 13B.

FIG. 14A shows forming a sidewall within the pore.

FIG. 14B is a view of FIG. 14A along section line 14B.

FIGS. 15A and 15B show deposition of resistive memory material within the pore.

FIG. 16A shows the fabrication process after a bit line is formed above the resistive memory material.

FIG. 16B is a view of FIG. 16A along section line 16B.

FIG. 17 is a view of FIG. 5 along section line 17.

FIG. 18A shows a pore formed in a dielectric layer, above and in physical contact with a second control metal layer.

FIG. 18B is a view of FIG. 18A along section line 18B.

FIG. 19A shows filling the pore with metallic material, then planarization of the structure.

FIG. 19B is a view of FIG. 19A along section line 19B.

FIGS. 20A and 20B show phase change material and top electrodes deposited and patterned over the metallic material within a dielectric layer.

FIGS. 21A and 21B show deposition and patterning of a bit line.

FIGS. 22A and 22B show a vertically stacked mushroom memory cell contemplated by the present invention.

FIG. 23A shows a substrate conditioned with the following vertical stack: a first terminal layer, a first control metal layer, a chalcogenide-based selector layer, a second control metal layer, a second terminal layer, a resistive memory layer, and a top electrode layer.

FIG. 23B is a view of FIG. 23A along section line 23B.

FIG. 24A shows access device fabrication after a stack etch is applied, with the first terminal layer used to form a word line.

FIG. 24B is a view of FIG. 24A along section line 24B.

FIG. 25A shows a dielectric layer deposited over and surrounding the access device and memory cell stack.

FIG. 25B is a view of FIG. 25A along section line 25B.

FIG. 26A shows a metal bit line layer and a second hard mask deposited over the access device and memory cell stack.

FIG. 26B is a view of FIG. 26A along section line 26B.

FIG. 27A shows the access device and memory cell stack etched, stopping on a first terminal layer.

FIG. 27B is a view of FIG. 27A along section line 27B.

FIG. 28A shows the resulting structure after a dielectric layer is deposited over and surrounding the access device stack.

FIG. 28B is a view of FIG. 28A along section line 28B.

FIGS. 29A and 29B show a vertically stacked memory array using a subtractive etch technique.

### DETAILED DESCRIPTION

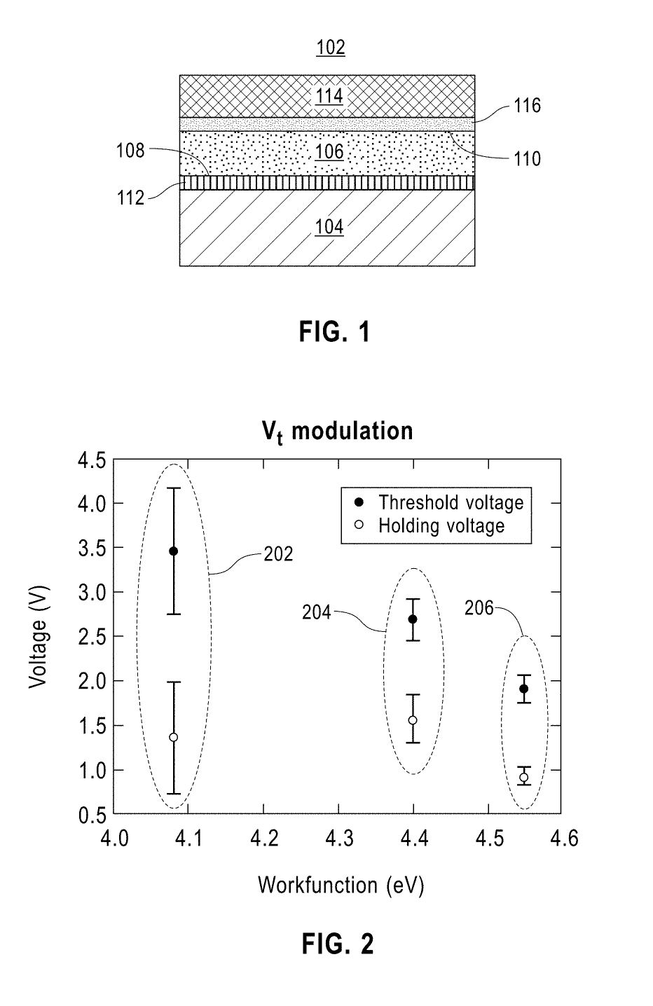

The present invention is described with reference to embodiments of the invention. Throughout the description of the invention reference is made to FIGS. 1-29B. When referring to the figures, like structures and elements shown throughout are indicated with like reference numerals.

Embodiments of the present invention include a selector switching layer with a sandwich structure of two materials: a metal rich layer and a chalcogenide rich layer. The selector switching layer is a single layer of chalcogenide rich material, where two (or one) additional metal electrodes are used to modulate the threshold voltage of the switching device.

Aspects of this invention propose a novel way of modulating the threshold voltage of chalcogenide-based selectors using an additional metal layer between the chalcogenide selector and the bit line and/or word line metal to control the threshold voltage of the selector. This structure allows independent selection of a low-resistance material for word lines and bit lines, as well as a threshold voltage tuning metal to modulate the selector on voltage.

FIG. 1 shows an example memory access device 102. The memory access device 102 includes a first terminal 104 with a first terminal workfunction. As used herein, a material's “workfunction” is the minimum quantity of energy is required to remove an electron to infinity from the surface of a given solid.” See “work function”, McGraw-Hill Dictionary of Scientific and Technical Terms, McGraw-Hill, p. 2303 (6th ed. 2003). Examples of materials for the first terminal 104 are copper (Cu) and tungsten (W).

The memory access device 102 includes a chalcogenide-based selector layer 106 with a first surface 108 and a second surface 110 opposite the first surface 108. Example chalcogenide materials include Arsenic (As), Germanium (Ge), Silicon (Si), sulfur (S), selenium (Se) and tellurium (Te). In one embodiment, the chalcogenide-based selector layer has a chalcogenide compound content of at least 48 mole percent.

A first control metal layer 112 is positioned in physical and electrical contact with the first terminal 104 and the first surface 108 of the chalcogenide-based selector layer 106. The first control metal layer includes a first control workfunction that is different than the first terminal workfunction. Examples of the first control metal layer 112 include, but are not limited to, titanium (Ti), titanium nitride (TiN), W, and aluminum (Al).

The memory access device 102 further includes a second control metal layer 116 in physical and electrical contact with a second terminal 114 and the second surface 110 of the chalcogenide-based selector layer 106. The second control metal layer 116 includes a second control workfunction.

The second terminal 114 is positioned in physical and electrical contact with the second control metal layer 116, and is positioned proximate the second surface 110 of the chalcogenide-based selector layer 106. The second terminal 114 includes a second terminal workfunction that is different than the second control workfunction. Examples of materials for the second terminal 114 include copper (Cu), silver (Ag), gold (Au), platinum (Pt) and W.

The memory access device 102 switches from a high-resistance device to a low-resistance device when an applied voltage across the first terminal and the second terminal equals a threshold voltage (Vth). The threshold voltage is dependent, in part, on the first control workfunction. Thus, the memory access device 102 exhibits current conduction above a threshold voltage Vth and high resistance below a holding voltage Vh.

The memory access device 102 provides a way of modulating the threshold voltage of chalcogenide based selector by using an additional metal layer between the chalcogenide selector and the bit line or word line metal to control the threshold voltage of the selector. Due to different layer workfunctions, the disclosed structure allows independent selection of a low resistance material for word lines and bit lines, as well as a threshold voltage tuning metal to modulate the selector on voltage. With the first control metal layer 112 and/or the second control metal layer 116 configuration of the present invention, it is not necessary to thin down the chalcogenide-based selector layer 106 to decrease the threshold voltage. This beneficially allows for lower leakage current and low power applications.

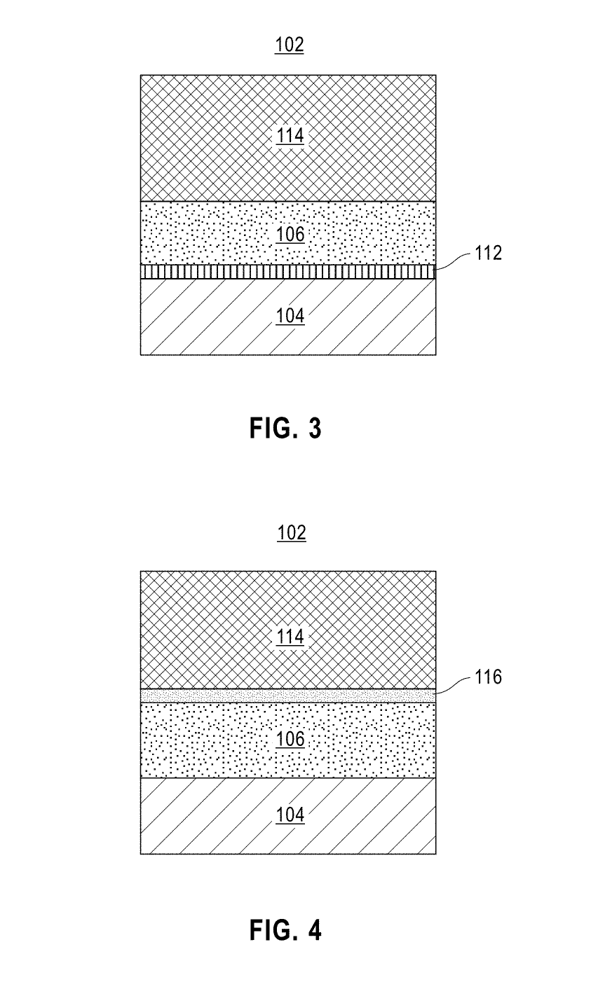

FIG. 2 is graph comparing threshold voltages of three different memory access devices contemplated by the present invention. The first device 202 uses Al control metal layers and has a Vth of approximately 3.4V and a Vh of approximately 1.4V. The second device 204 uses TiN control metal layers and has a Vth of approximately 2.7V and a Vh of approximately 1.6V. The third device 206 uses W control metal layers and has a Vth of approximately 1.9V and a Vh of approximately 0.9V. Thus, the threshold voltages (Vth and Vh) of the memory access device can be tuned by appropriate selection of the first and/or second control metal layer.

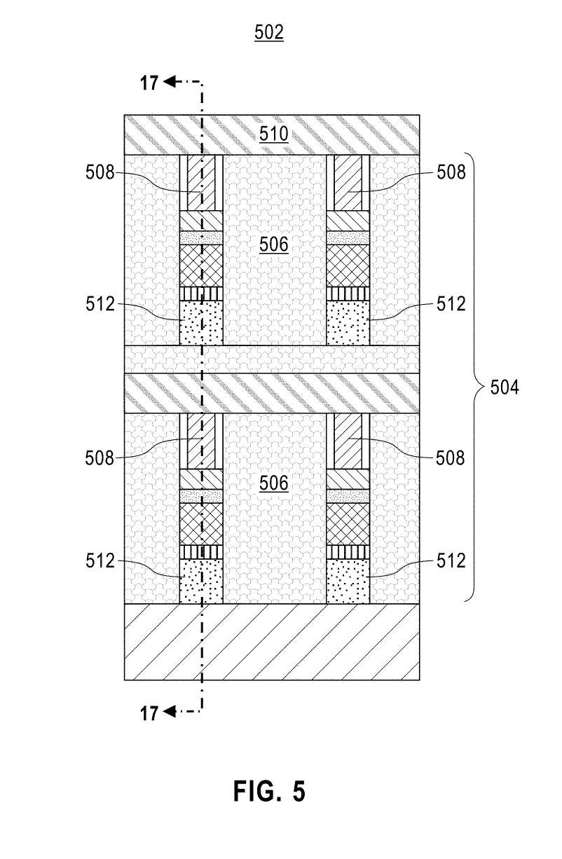

FIG. 3 shows an alternate example embodiment of the memory access device 102. This memory access device 102 includes a first terminal 104, a first control metal layer 112, a chalcogenide-based selector layer 106, and a second terminal 114, as discussed above. However, the embodiment does not contain a second control metal layer 116 above the chalcogenide-based selector layer 106 and in physical contact with the second terminal 114.

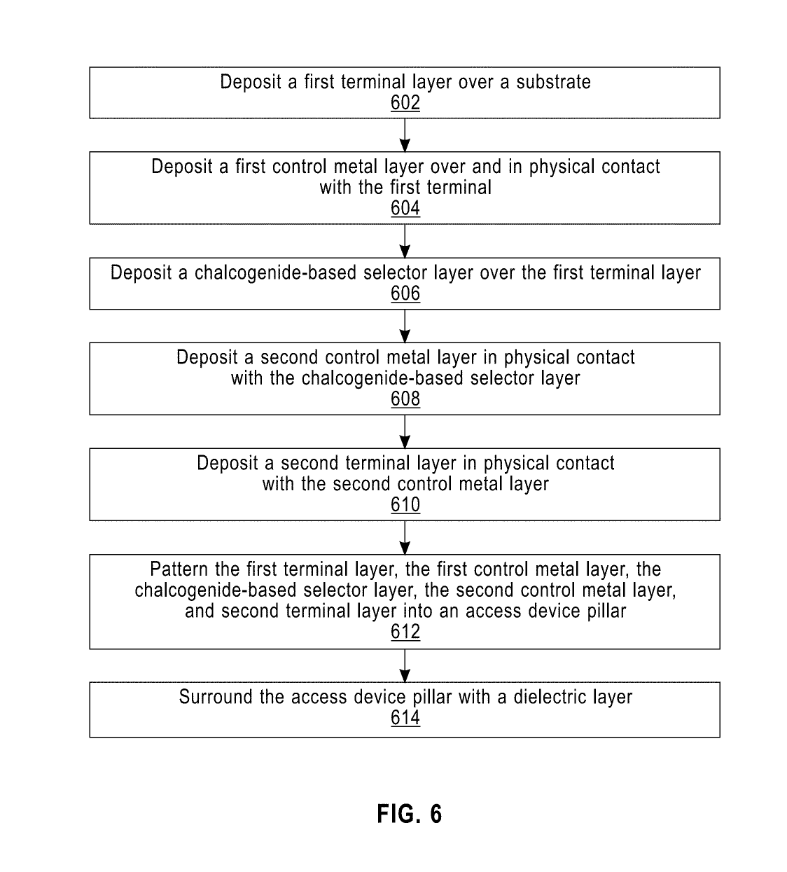

FIG. 4 shows another alternate example embodiment of the memory access device 102. The memory access device 102 includes a first terminal 104, a chalcogenide-based selector layer 106, a second control metal layer 116, and a second terminal 114, as discussed above. However, this embodiment does not contain a first control metal layer 116 below the chalcogenide-based selector layer 106 and in physical contact with the first terminal 104.

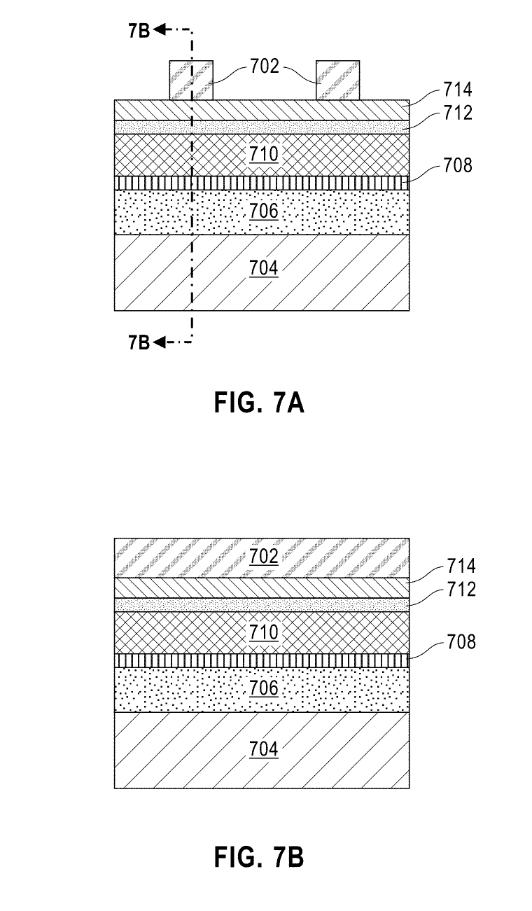

FIG. 5 shows an example embodiment of a memory device 502 contemplated by the present invention. The device includes an array of memory cells 504. Each memory cell 504 in the array includes an access device 506 and a resistive memory 508. A bit line 510 is connected to a first group of memory cells and a word line 512 running perpendicular to the bit line 510 is connected to a second group of memory cells.

As discussed above, the access device 506 includes a first terminal with a first terminal workfuntion, a chalcogenide-based selector layer, a first control metal layer in physical and electrical contact with the first terminal and a first surface of the chalcogenide-based selector layer. The first control metal layer includes a first control workfunction different than the first terminal workfunction. A second control metal layer has a second control workfunction and is in physical and electrical contact with a second surface of the chalcogenide-based selector layer. A second terminal is in physical contact with second control metal layer. Furthermore, the second terminal has a second terminal workfunction different than the second control workfunction.

The resistive memory 508 is electrically coupled to the access device 506 and is programmable to at least two resistive states. In one embodiment, the resistive memory 508 includes phase change material (PCM). The phase change material may be a material programmable to either a first phase having a first electrical resistance or a second phase having a second electrical resistance, where the first electrical resistance is greater than the second electrical resistance. In one embodiment, the phase change material may include a Germanium-Antimony-Tellurium (GST) compound, such as Ge₂Sb₂Te₅. Other phase change materials, such as SbTe and In₂Se₃, may also be used by the present invention. In one embodiment, the phase change memory array is a multi-bit memory array. Thus, the phase change material is programmed to one of at least three resistance levels. In another embodiment, the resistive memory 508 includes a resistive random-access memory (RRAM). RRAM is typically memory based on a dielectric layer, such as HfO₂-based memory and AlO₂-based memory.

As shown, the memory cells 504 may be vertically stacked in a three-dimensional memory array. Thus, one memory access device may be vertically stacked above another memory access device.

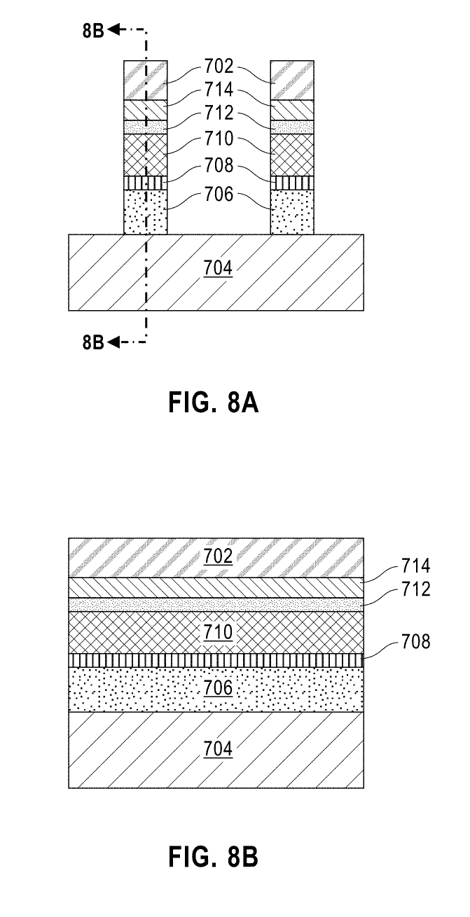

FIG. 6 shows an example method for fabricating a memory access device, as contemplated by the present invention. The method includes depositing operation 602. During this operation, a first terminal layer is deposited over a substrate. Various materials may be used for the terminal layer, such as Cu, Ag, Au, Pt, and W. Furthermore, the first terminal layer has a first terminal workfunction. After depositing operation 602, process flow continues to depositing operation 604.

At depositing operation 604, a first control metal layer is deposited over, and in physical and electrical contact with, the first terminal layer. This operation may include receiving Vth and Vh design requirements and selecting a control metal layer material that achieves the specified Vth and Vh design requirements. Example materials for the control metal layer include Ti, TiN, W, and Al. The operation includes selecting the first control metal layer to have a first control workfunction different than the first terminal workfunction, such that the threshold voltages (Vth and Vh) of the memory access devices are tuned to desired values. For example, a designer may select a material for the first control metal layer providing a turn on threshold Vth of 2.7V for a memory array operating at 3.3V. After depositing operation 604, process flow continues to depositing operation 606.

At depositing operation 606, a chalcogenide-based selector layer is deposited over the first terminal layer. Example chalcogenide materials include O, S, Se, and Te. In one embodiment, the chalcogenide-based selector layer has a chalcogenide compound content of at least 50 mole percent. After depositing operation 606, process flow continues to depositing operation 608.

At depositing operation 608, a second control metal layer is deposited in physical contact with the chalcogenide-based selector layer, with the second control metal layer including a second control workfunction. Again, this operation includes selecting a control metal layer material such that the threshold voltages (Vth and Vh) of the memory access devices are tuned to desired values. After depositing operation 608, process flow continues to depositing operation 610.

At depositing operation 610, a second terminal layer is deposited in physical contact with the second control metal layer. The second control metal layer includes a second terminal workfunction different than the second terminal workfunction. After depositing operation 610, process flow continues to patterning operation 612.

At patterning operation 612, the first terminal layer, the first control metal layer, the chalcogenide-based selector layer, the second control metal layer, and the second terminal layer are patterned into an access device pillar. In one embodiment, patterning operation 612 is performed using a reactive ion etch (RIE). In one embodiment, the sidewall of the chalcogenide-based selector may need to be protected prior to patterning. After patterning the threshold switching material, but before patterning the bottom control metal and terminal layers, the exposed sidewall of the chalcogenide material may need to be protected by a thin layer (typically SiN or SiO2 but possibly HfO2 and Al2O3) conformally deposited (usually ALD or CVD) so that further RIE chemistry will not interact with the chalcogenide switching layer.

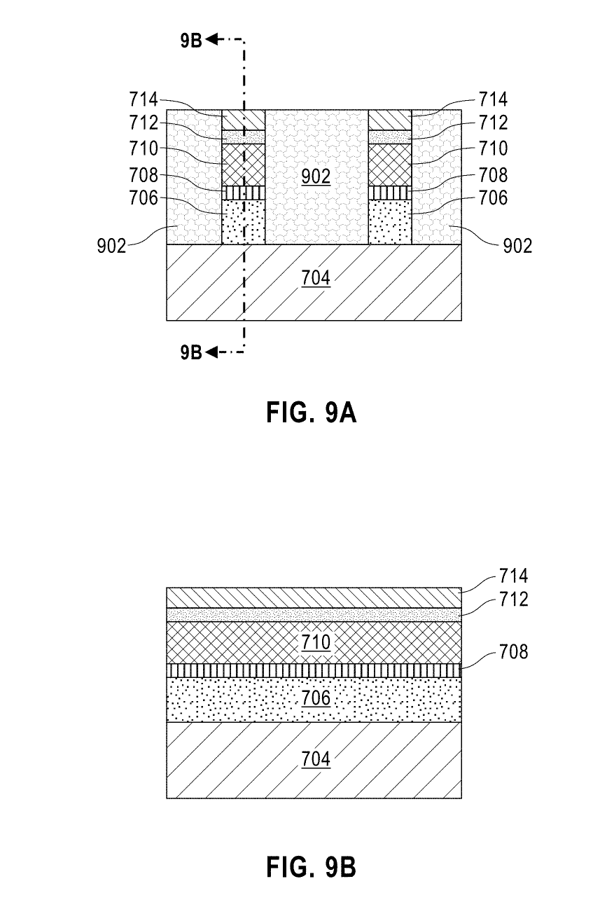

FIG. 7A shows a hard mask layer 702 applied over layers forming the memory access device. Specifically, the hard mask 702 is positioned above a silicon (Si) substrate 704, the first terminal layer 706, the first control metal layer 708, the chalcogenide-based selector layer 710, the second control metal layer 712, and the second terminal layer 714. FIG. 7B is a view of FIG. 7A along section line 7B. The hard mask 702 is applied prior to a stack etch of the access device.

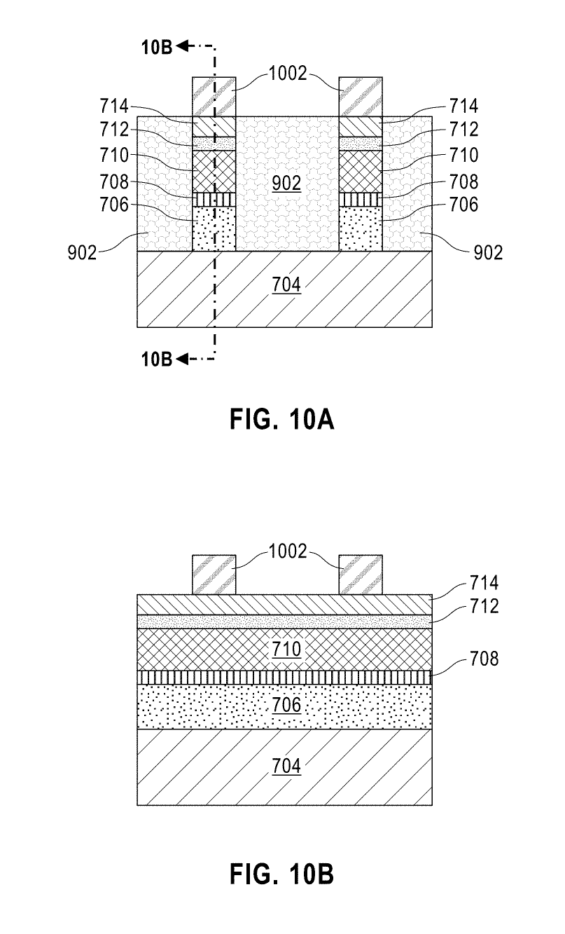

FIG. 8A shows access device fabrication after a stack etch is applied, with the first terminal layer 706 used to form a word line. In one embodiment, the stack etch is accomplished using a reactive ion etch (RIE) stopping at the substrate 704. FIG. 8B is a view of FIG. 8A along section line 8B.

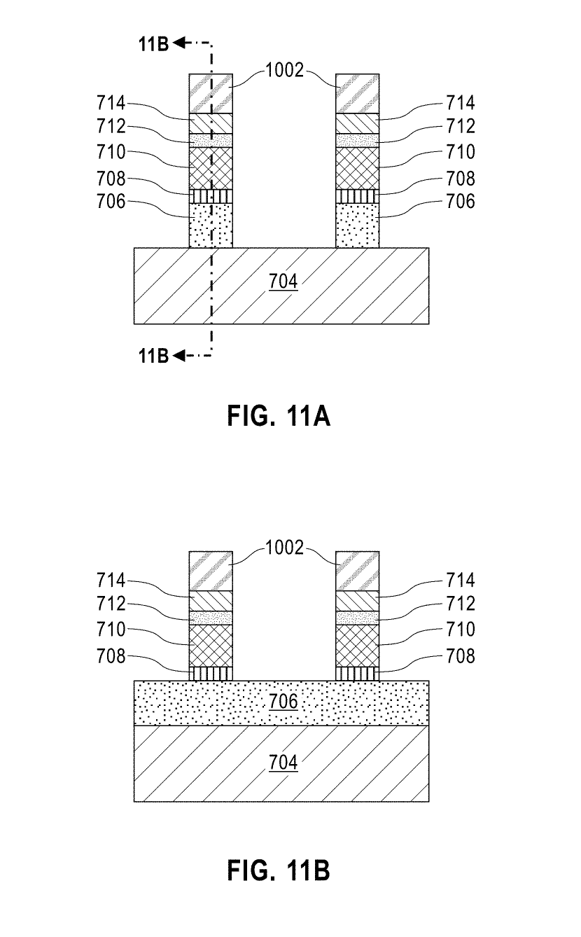

Next, as shown in FIG. 9A, a dielectric layer 902, such as SiO₂ or SiN, or a low-k dielectric such as SiCOH, is deposited over and surrounding the access device stack. The dielectric layer 902 is then polished. In one embodiment, a chemical mechanical polish (CMP) is performed. FIG. 9B is a view of FIG. 9A along section line 9B.

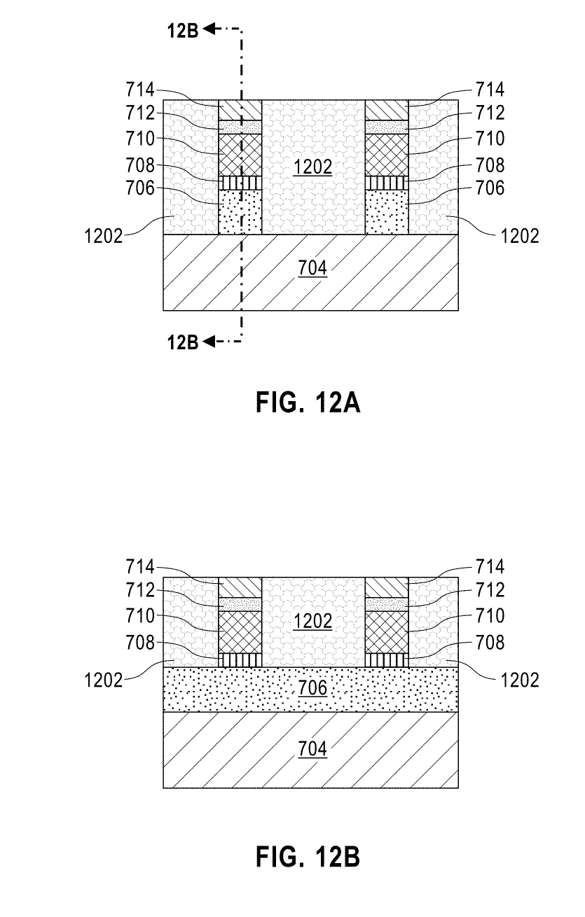

At FIG. 10A, a second hard mask 1002 is deposited and patterned over the access device layers. In one embodiment, the hard masks used are lithographic masks. FIG. 10B is a view of FIG. 10A along section line 10B.

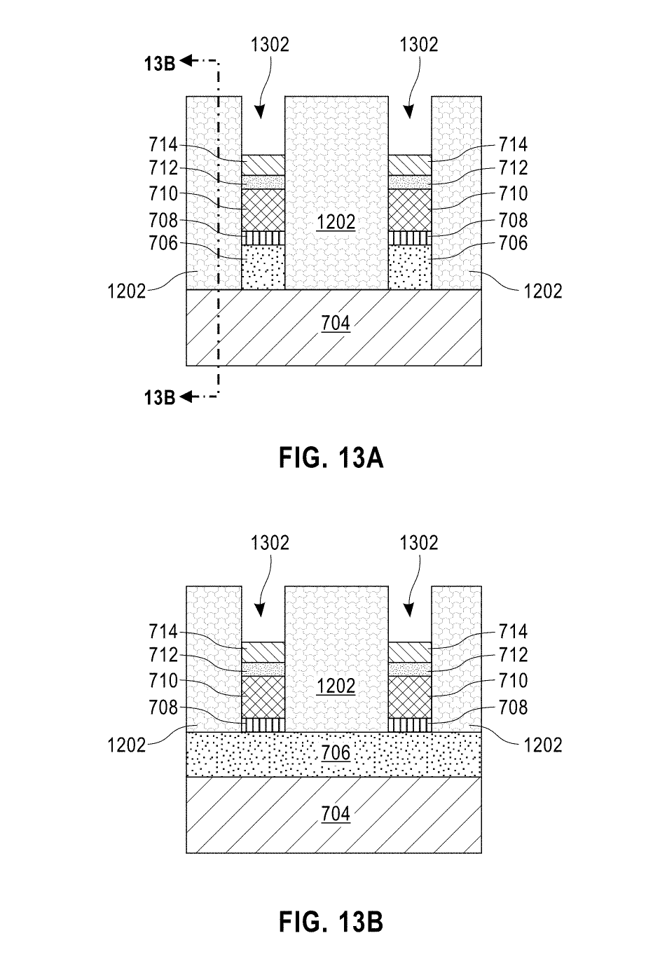

Next, at FIG. 11A, the access device is etched again, stopping on the first terminal layer 706. This etch forms a pillar structure from the first control metal layer 708 to the second terminal layer 714. FIG. 11B is a view of FIG. 11A along section line 11B.

Returning to FIG. 6, after patterning operation 612, process flow continues to surrounding operation 614. At surrounding operation 614, the access device pillar is surrounded with a dielectric layer. In one embodiment, the dielectric layer may be SiO₂ or SiN.

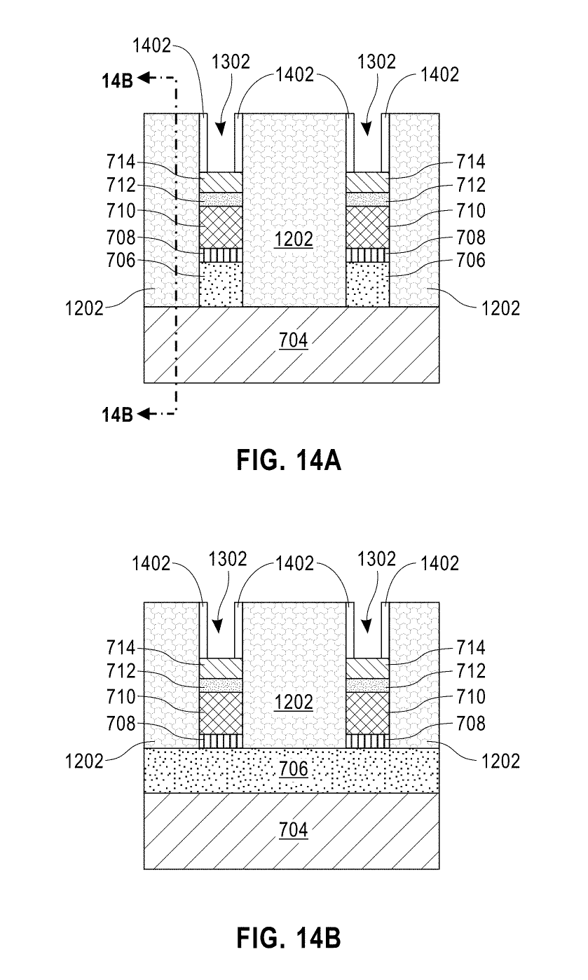

FIG. 12A shows the resulting structure after surrounding operation 614. A dielectric layer 1202 is deposited over and surrounding the access device stack. The dielectric layer 1202 is then polished. FIG. 12B is a view of FIG. 12A along section line 12B.

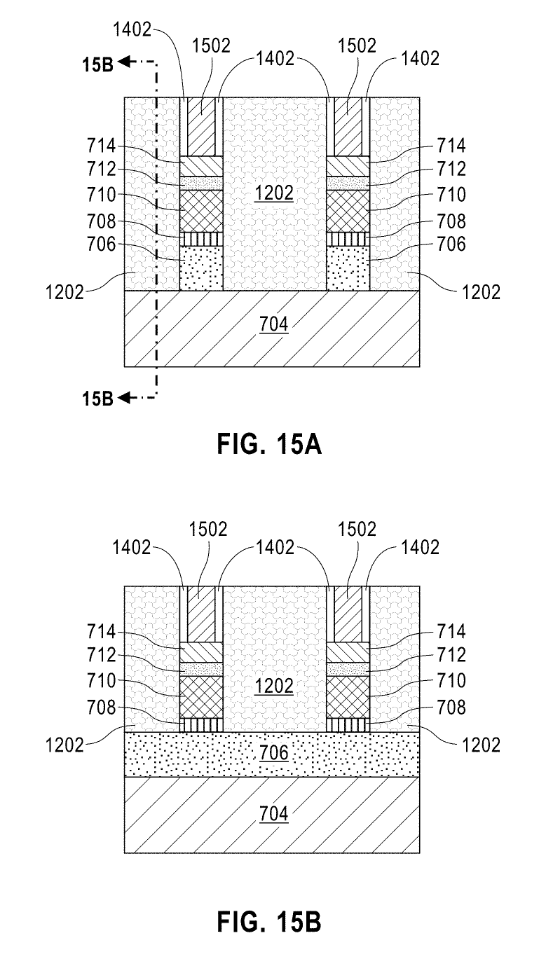

In some embodiments, the access device is coupled to resistive memory. Thus, the fabrication method may include forming a pore 1302 within the dielectric layer 1202, above and in physical contact with the second control metal layer, as shown in FIG. 13A. FIG. 13B is a view of FIG. 13A along section line 13B.

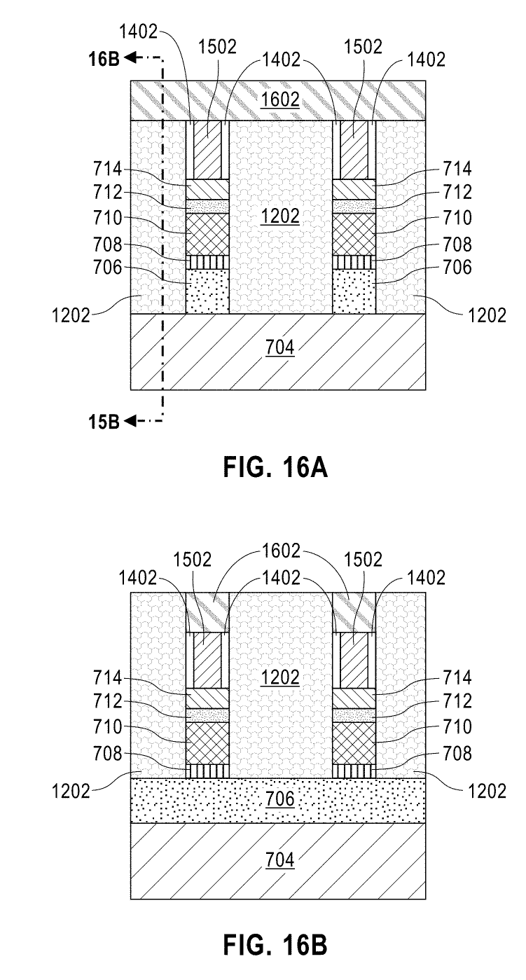

Next, as shown in FIG. 14A, the fabrication method may include forming a sidewall 1402 within the pore 1302. In one embodiment, the sidewall 1402 comprises metallic material, such as metal nitride, and extends from the bottom of the pore to the top of the pore. The sidewall creates a second pore with a smaller volume than the first pore. Additionally, the sidewall can beneficially attenuate the resistance drift of phase change memories. FIG. 14B is a view of FIG. 14A along section line 14B.

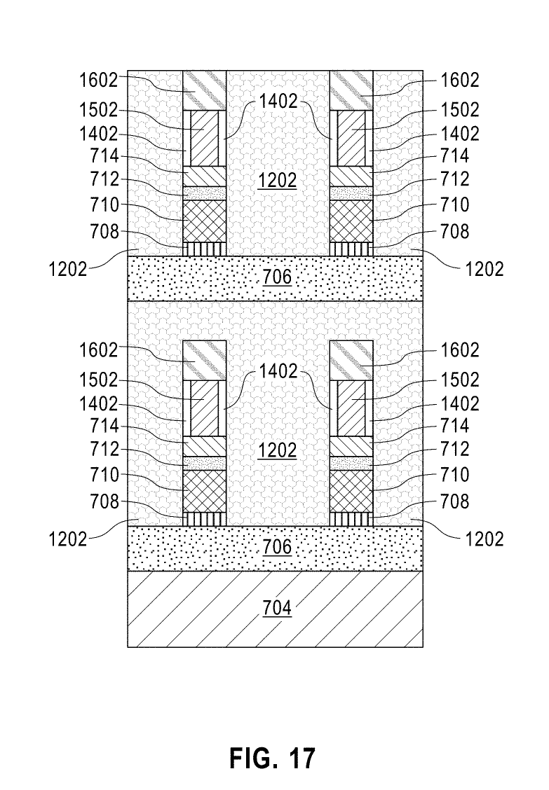

After forming the sidewall 1402, the fabrication method includes depositing resistive memory material 1502 within the pore, as shown in FIGS. 15A and 15B. The resistive memory material is programmable to at least two resistive states. Deposition of the resistive memory material may be followed by a RIE etch back or CMP. The resistive memory material may be, for example, phase change material (PCM) or resistive random-access memory (RRAM) material.

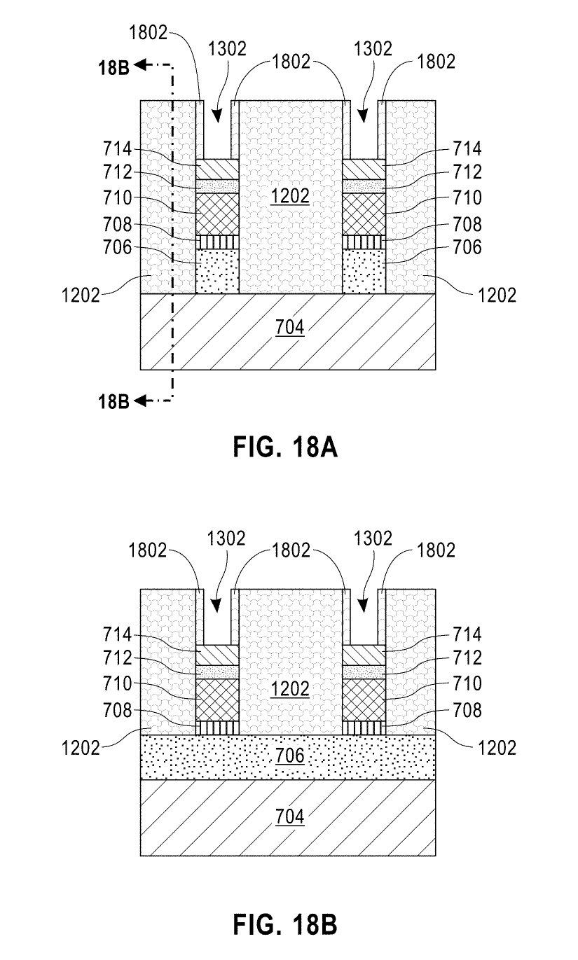

FIG. 16A shows the fabrication process after a bit line 1602 is formed above the resistive memory material 1502. This step includes metal deposition, patterning, a dielectric fill, and polish. FIG. 16B is a view of FIG. 16A along section line 16B.

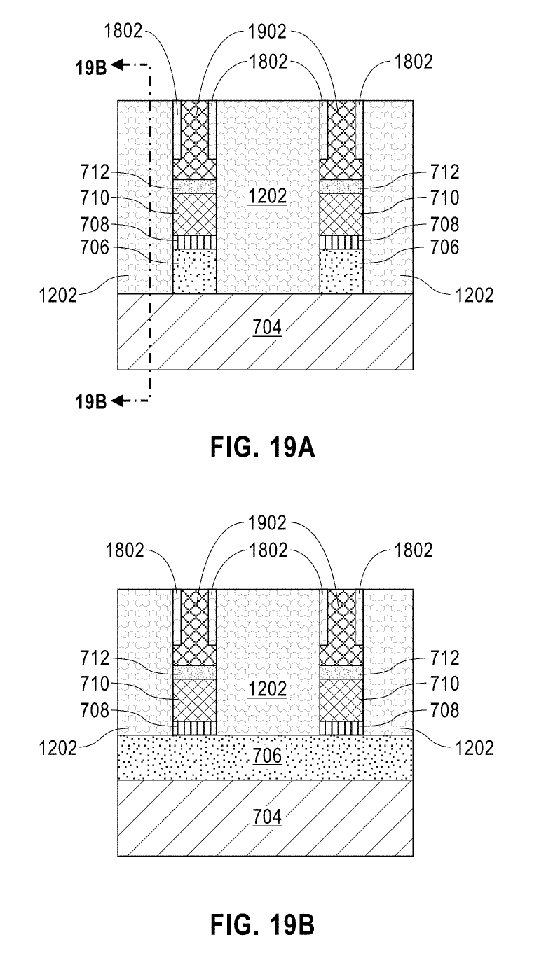

As mentioned above, embodiments of the present invention may be stacked vertically, as shown in FIG. 5. In this fabrication process, the Vth control layers are at both sides of the chalcogenide based selector. However, the Vth control layers could be also only be fabricated on one side of the chalcogenide based selector. FIG. 17 is a view of FIG. 5 along section line 17.

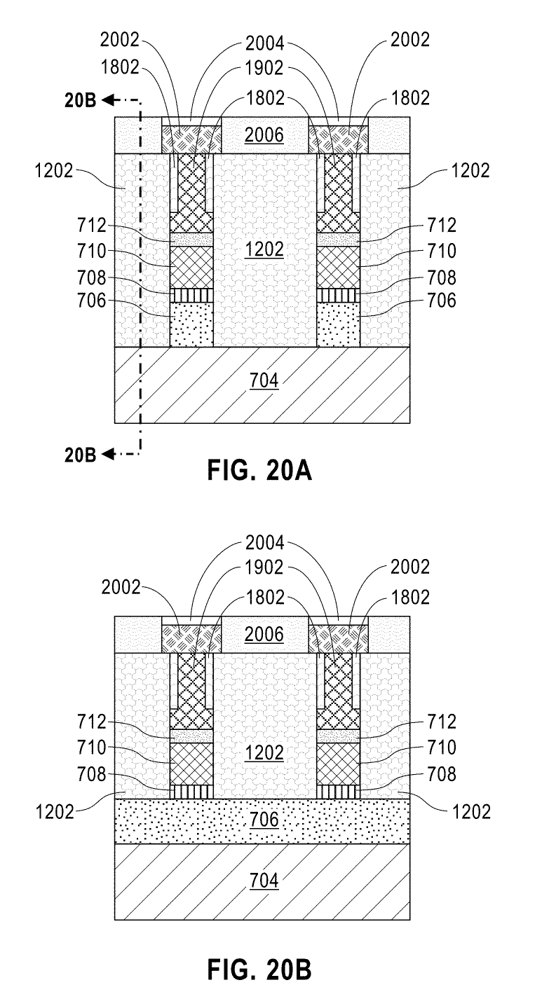

In another embodiment, the memory cell may be fabricated as a “mushroom” type memory cell with a sidewall 1802, as shown in FIGS. 18A-25. Starting with FIG. 18A, a pore 1302 is formed the dielectric layer 1202, above and in physical contact with the second control metal layer 714. FIG. 18B is a view of FIG. 18A along section line 18B.

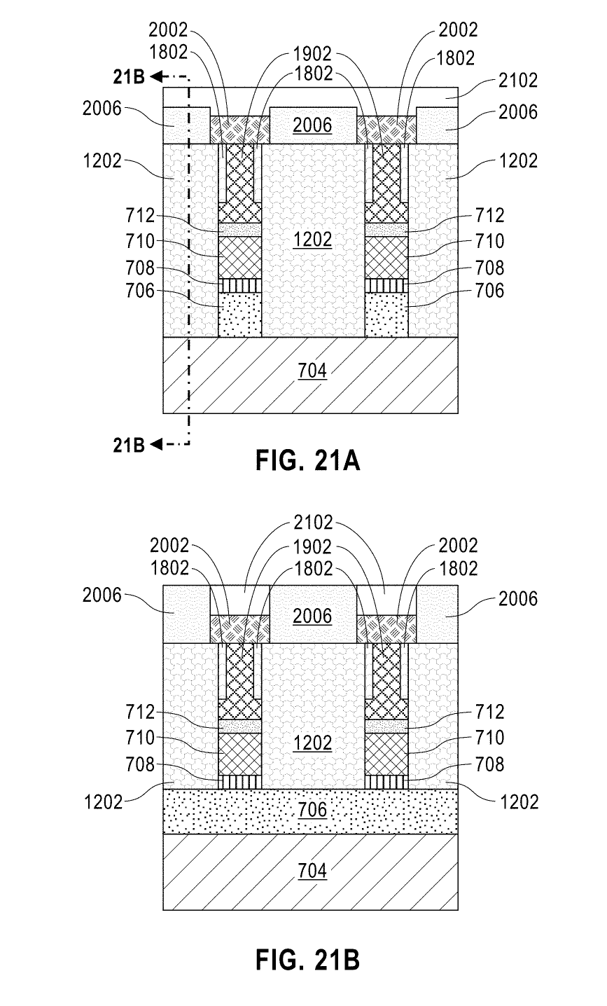

Next, as shown in FIG. 19A, the fabrication method includes filling the pore with metallic material 1902, then planarizing the structure (i.e., a CMP operation). FIG. 19B is a view of FIG. 19A along section line 19B.

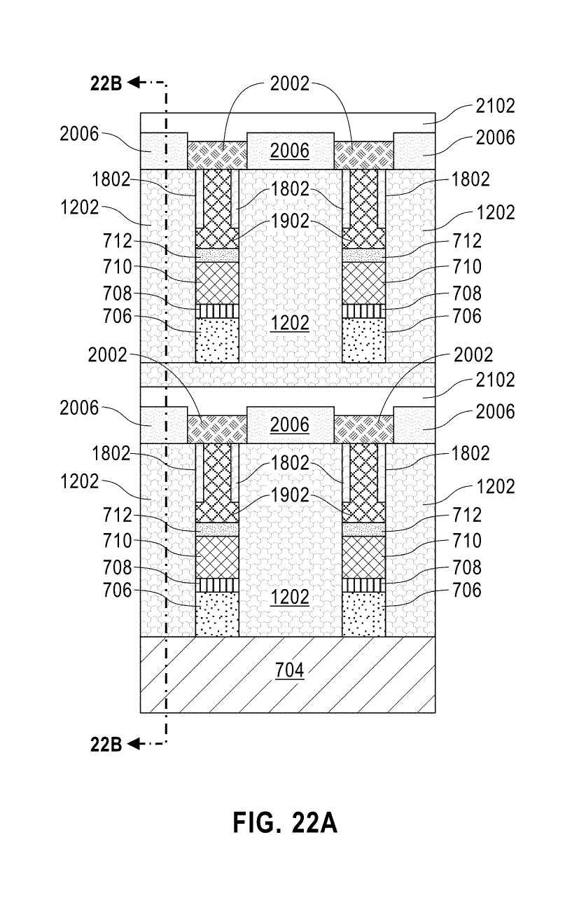

Next, as shown in FIGS. 20A and 20B, PCM 2002 and top electrodes 2004 are deposited and patterned over the metallic material 1902 within a dielectric layer 2006. Specifically, the PCM 2002 is positioned between and in physical contact with both the metallic material 1902 and the top electrode 2004. FIG. 20B is a view of FIG. 20A along section line 20B.

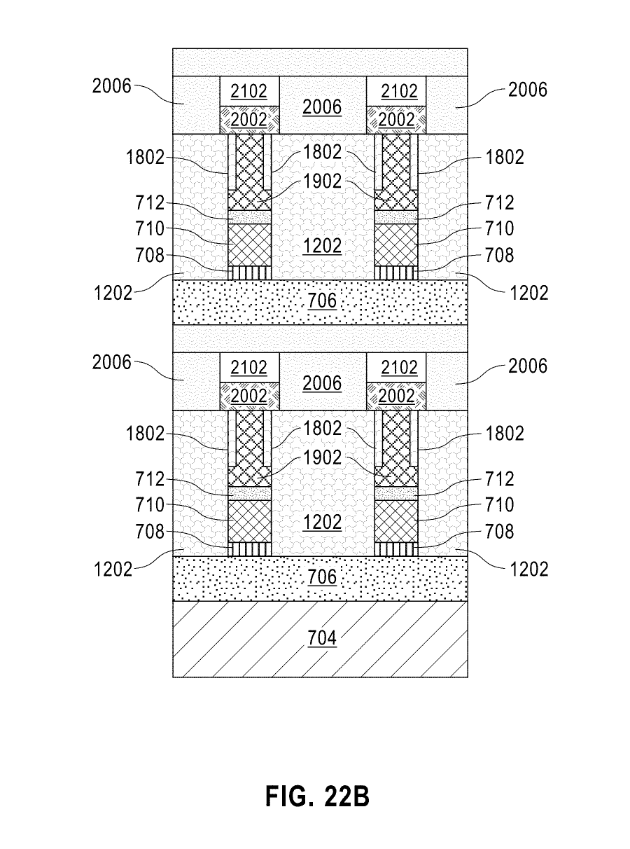

In FIGS. 21A and 21B, deposition of a bit line 2102 is shown. This step includes metal deposition, patterning, a dielectric fill, and polish. FIG. 21B is a view of FIG. 21A along section line 21B.

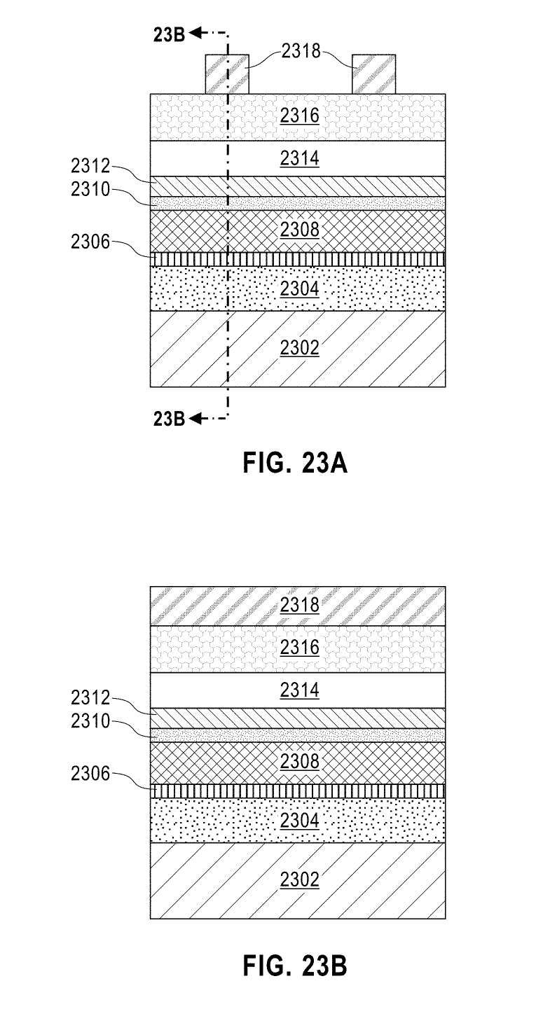

FIGS. 22A and 22B show a vertically stacked mushroom memory cell contemplated by the present invention. Although the Vth control layers are shown on both sides of the chalcogenide based selector, other embodiments may include the Vth control layers fabricated on only one side of the chalcogenide based selector. FIG. 22B is a view of FIG. 22A along section line 22B.

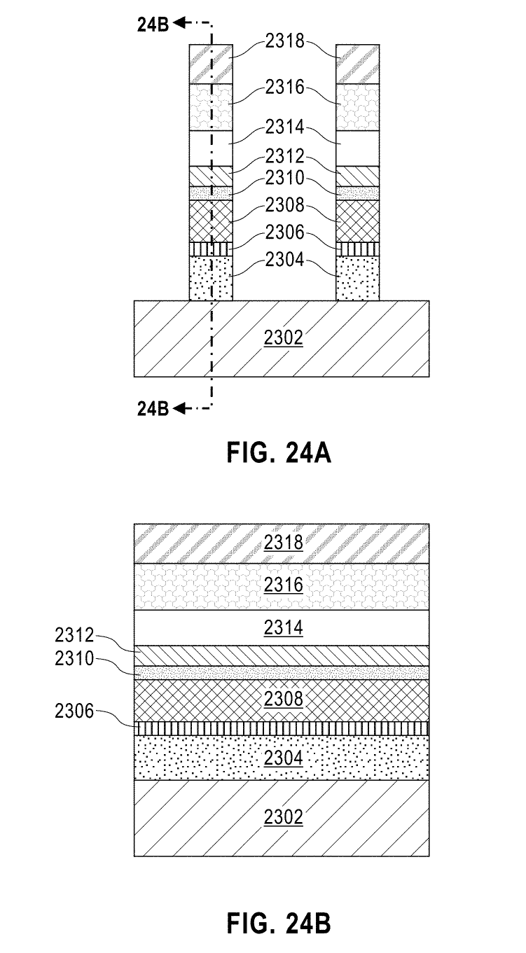

FIGS. 23A-28B show another embodiment of a method of fabricating a memory array contemplated by the present invention. In this embodiment, the access device and memory cell are subtractively etched.

As shown in FIG. 23A, a Si substrate 2302 is conditioned with the following vertical stack: a first terminal layer 2304, a first control metal layer 2306, a chalcogenide-based selector layer 2308, a second control metal layer 2310, a second terminal layer 2312, a resistive memory layer 2314, and a top electrode layer 2316. In one embodiment, the stack layers are deposited using physical vapor deposition (PVD). A hard mask 2318 is then patterned above the stack. FIG. 23B is a view of FIG. 23A along section line 23B. Those skilled in the art will observe that, in other embodiments of the present invention, the stack may be inverted with selector layer 2308 and control metal layer(s) positioned above the resistive memory layer 2314.

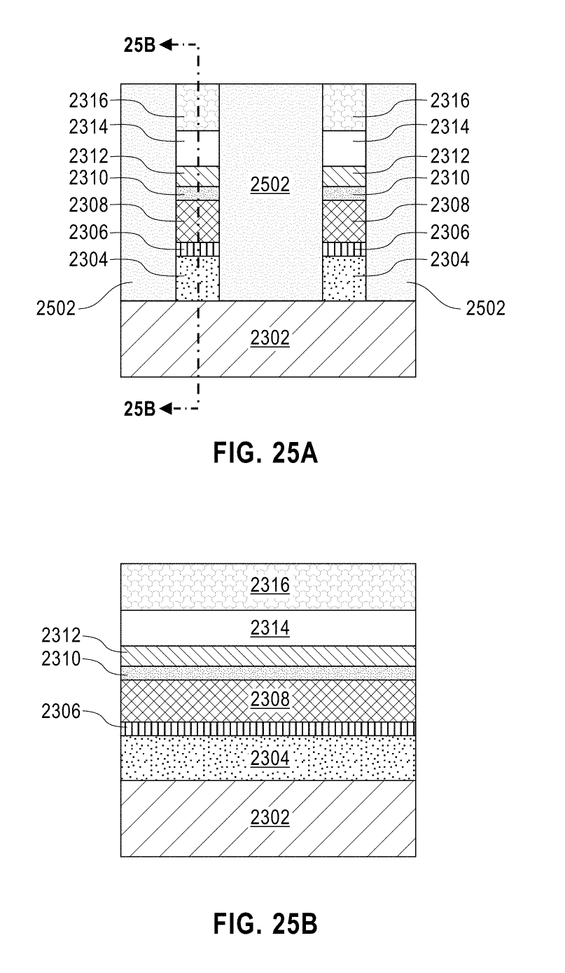

FIG. 24A shows access device fabrication after a stack etch is applied, with the first terminal layer 2304 used to form a word line. In one embodiment, the stack etch is accomplished using a RIE stopping on the substrate 2302. FIG. 24B is a view of FIG. 24A along section line 24B. In one embodiment, the sidewall of the chalcogenide-based selector may need to be protected prior to patterning. After patterning the threshold switching material, but before patterning the bottom control metal and terminal layers, the exposed sidewall of the chalcogenide material may need to be protected by a thin layer (typically SiN or SiO2 but possibly HfO2 and Al2O3) conformally deposited (usually ALD or CVD) so that further RIE chemistry will not interact with the chalcogenide switching layer.

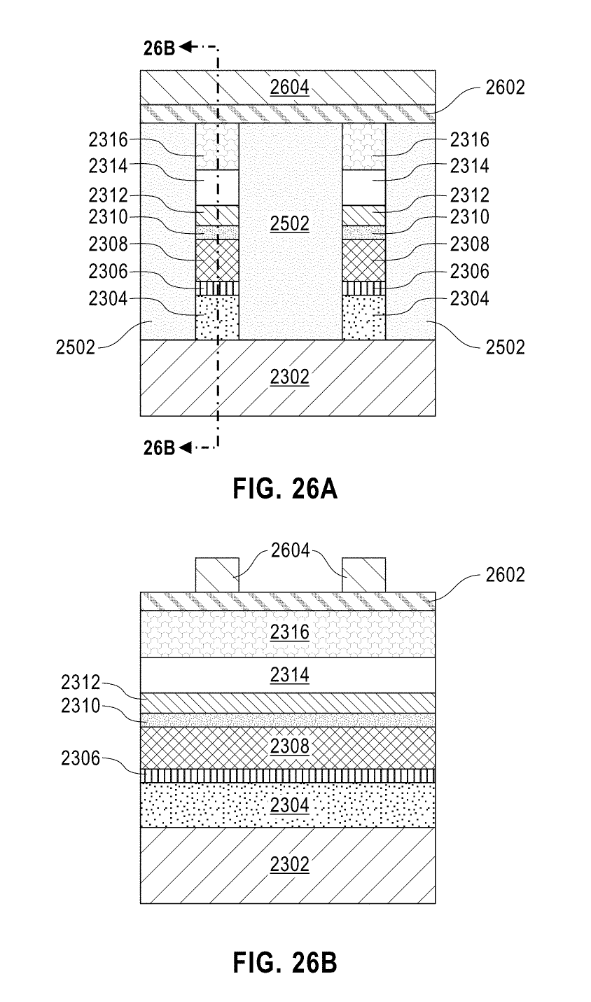

Next, as shown in FIG. 25A, a dielectric layer 2502, such as SiO2 or SiN (or low-k dielectric such as SiCOH), is deposited over and surrounding the access device and memory cell stack. The dielectric layer 2502 is then polished. In one embodiment, a CMP is performed. FIG. 25B is a view of FIG. 25A along section line 25B.

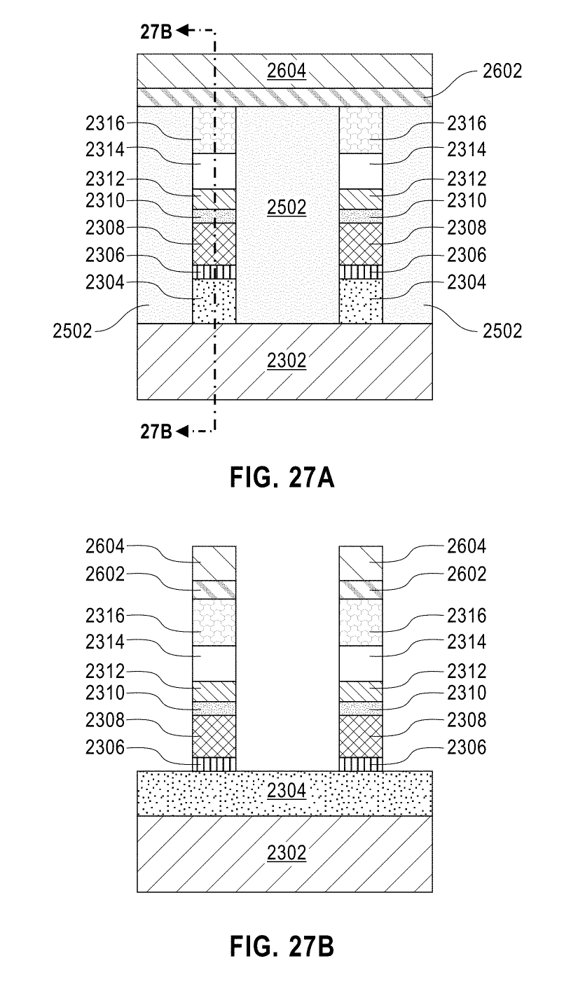

At FIG. 26A, metal bit line layer 2602 and a second hard mask 2604 are deposited over the access device and memory cell stack. The hard mask 2604 is patterned to run perpendicular to the first terminal layer 2304. FIG. 26B is a view of FIG. 26A along section line 26B.

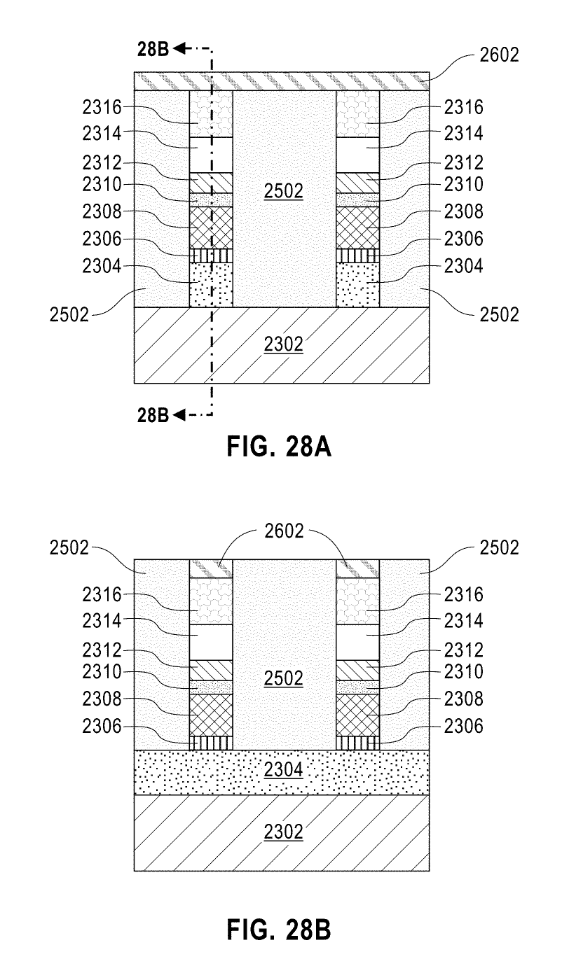

Next, at FIG. 27A, the access device and memory cell stack is etched again, stopping on the first terminal layer 2304. This etch forms a pillar structure from the first control metal layer 2306 to the top electrode layer 2316. FIG. 27B is a view of FIG. 27A along section line 27B.

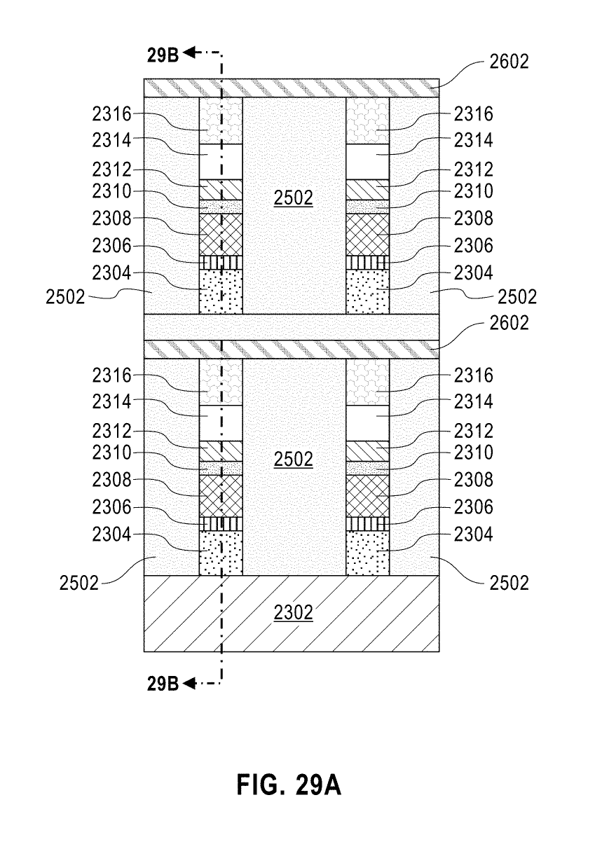

FIG. 28A shows the resulting structure after a dielectric layer 2802 is deposited over and surrounding the access device stack. The dielectric layer 2802 is then polished. FIG. 28B is a view of FIG. 28A along section line 28B.

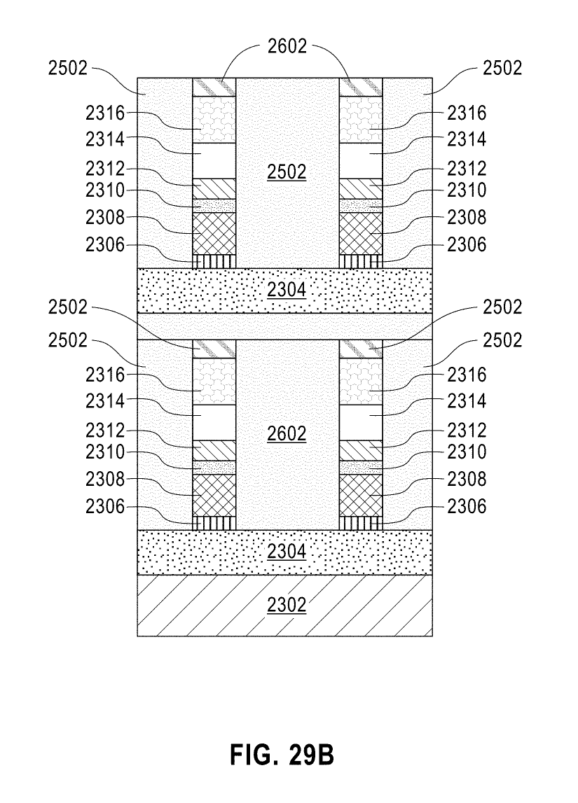

FIGS. 29A and 29B show a vertically stacked memory array using the subtractive etch technique described above. Although the Vth control layers are shown on both sides of the chalcogenide based selector, other embodiments may include the Vth control layers fabricated on only one side of the chalcogenide based selector. FIG. 29B is a view of FIG. 29A along section line 29B.

As described above, embodiments of the present invention can provide configurations for tuning access devices in a two and three-dimensional memory array (3D memory array). An aspect of the present invention can provide a 2D or 3D memory array with programmable memory cells arranged such that each memory cell is programmable and readable by biasing word lines and bit lines.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

What is claimed is:

1. A memory access device comprising:
a first terminal including a first terminal workfunction;
a chalcogenide-based selector layer including a first surface and a second surface opposite the first surface;
a first control metal layer in physical and electrical contact with the first terminal and the first surface of the chalcogenide-based selector layer, the first control metal layer including a first control workfunction different than the first terminal workfunction; and
a second terminal including a second terminal workfunction, the second terminal positioned proximate the second surface of the chalcogenide-based selector layer.

2. The memory access device of claim 1, wherein the memory accesses device switches from a high-resistance device to a low-resistance device when an applied voltage across the first terminal and the second terminal equals a threshold voltage (Vth), the threshold voltage (Vth) is dependent, in part, on the first control workfunction.

3. The memory access device of claim 1, further comprising a second control metal layer in physical and electrical contact with the second terminal and the second surface of the chalcogenide-based selector layer, the second control metal layer including a second control workfunction different than the second terminal workfunction.

4. The memory access device of claim 1, further comprising phase change material (PCM) electrically coupled to the second terminal.

5. The memory access device of claim 1, further comprising a resistive random-access memory (RRAM) electrically coupled to the second terminal.

6. The memory access device of claim 1, wherein the memory access device is vertically stacked above a second memory access device.

7. A method for fabricating a memory access device, the method comprising:
depositing a first terminal layer over a substrate, the first terminal layer including a first terminal workfunction;
depositing a first control metal layer over and in physical contact with the first terminal layer, the first control metal layer including a first control workfunction different than the first terminal workfunction;
depositing a chalcogenide-based selector layer over the first terminal layer;
depositing a second control metal layer over and in physical contact with the chalcogenide-based selector layer, the second control metal layer including a second control workfunction;
depositing a second terminal layer over and in physical with the second control metal layer, the second control metal layer including a second terminal workfunction different than the second terminal workfunction; and
patterning the first control metal layer, the chalcogenide-based selector layer, and the second control metal layer into an access device pillar.

8. The method of claim 7, further comprising surrounding the access device pillar with a dielectric layer.

9. The method of claim 7, further comprising:
forming a pore above and in physical contact with the second control metal layer;
forming a sidewall within the pore; and
depositing resistive memory material within the pore, the resistive memory material is programmable to at least two resistive states.

10. The method of claim 9, wherein the resistive memory material is phase change material (PCM).

11. The method of claim 9, wherein the resistive memory material is resistive random-access memory (RRAM) material.

12. The method of claim 7, further comprising:
forming a pore above and in physical contact with the second control metal layer;
forming a sidewall within the pore; and
depositing conductive material within the pore; and
depositing resistive memory material above and in physical contact with the conductive material, the resistive memory material is programmable to at least two memory states.

13. The method of claim 12, wherein the resistive memory material is phase change material (PCM).

14. The method of claim 12, wherein the resistive memory material is resistive random-access memory (RRAM) material.

15. The method of claim 7, further comprising vertically stacking the memory access device above a second memory access device.

16. A memory device comprising:
an array of memory cells, each memory cell in the array of memory cells including:
an access device including a first terminal including a first terminal workfunction, a chalcogenide-based selector layer including a first surface and a second surface opposite the first surface, a first control metal layer in physical and electrical contact with the first terminal and the first surface of the chalcogenide-based selector layer, the first control metal layer including a first control workfunction different than the first terminal workfunction, and a second terminal including a second terminal workfunction, the second terminal positioned proximate the second surface of the chalcogenide-based selector layer; and
a resistive memory electrically coupled to the access device, the resistive memory material is programmable to at least two resistive states.

17. The memory device of claim 16, wherein the memory accesses device of each of the memory cells switches from a high-resistance device to a low-resistance device when an applied voltage across the first terminal and the second terminal equals a threshold voltage (Vth), the threshold voltage (Vth) is dependent, in part, on the first control workfunction.

18. The memory device of claim 16, wherein the memory accesses device of each of the memory cells includes a second control metal layer in physical and electrical contact with the second terminal and the second surface of the chalcogenide-based selector layer, the second control metal layer including a second control workfunction different than the second terminal workfunction.

19. The memory device of claim 16, wherein the resistive memory includes phase change material (PCM) electrically coupled to the second terminal.

20. The memory device of claim 16, wherein the resistive memory includes a resistive random-access memory (RRAM) electrically coupled to the second terminal.
